(19) United States
(12) Patent Application Publication
(10) Pub. No.: US 2025/0296242 A1
(43) Pub. Date: Sep. 25, 2025

(54) Gripper for Handling SMD Component Reel Cassettes, and Associated SMD Component Reel Cassette

(71) Applicant: KUKA Deutschland GmbH, Augsburg (DE)

(72) Inventors: Erich Block, Augsburg (DE); Adil Akbas, Augsburg (DE); Pascal Caprano, Augsburg (DE); Friedrich Sterz, Augsburg (DE)

(73) Assignee: KUKA Deutschland GmbH, Augsburg (DE)

(21) Appl. No.: 18/860,899

(22) PCT Filed: Apr. 27, 2023
(86) PCT No.: PCT/EP2023/061120

§ 371 Date: Oct. 28, 2024

(30) Foreign Application Priority Data
May 2, 2022 (DE) 10 2022 110 772.8

(51) Int. Cl. B25J 15/00; H05K 13/02

(52) U.S. Cl. CPC B25J 15/0004; H05K 13/02

(57) ABSTRACT

A gripper for handling SMD component reel cassettes using a robotic arm automatically controlled by a robot controller wherein the robotic arm carries and manipulates the gripper on a tool flange of the robotic arm. The gripper includes a drive pinion, which is rotatably mounted on the gripper main body and is designed to mesh with an output wheel of the SMD component reel cassette when the SMD component reel cassette is coupled to the gripper. The gripper includes a drive motor, which is disposed on the gripper main body and is designed to automatically drive the drive pinion.

### CROSS-REFERENCE TO RELATED APPLICATIONS

This application is a national phase application under 35 U.S.C. § 371 of International Patent Application No. PCT/EP2023/061120, filed Apr. 27, 2023 (pending), which claims the benefit of priority to German Patent Application No. DE 10 2022 110 772.8, filed May 2, 2022, the disclosures of which are incorporated by reference herein in their entirety.

### TECHNICAL FIELD

The invention relates to a gripper for handling SMD component reel cassettes by means of a robotic arm automatically controlled by a robot controller, when the robotic arm carries and manipulates the gripper on a tool flange of the robotic arm. The invention also relates to an associated SMD component reel cassette.

### BACKGROUND

CN 212711952 U relates to the technical field of SMT material receiving devices, in particular to an SMT material receiving machine comprising a suction device for sucking a material-receiving tape, a pressure roller and a drive device, wherein the drive device is connected to the suction device and the pressure roller and the drive device drives the suction device to suck the material-receiving tape and to convey the material-receiving tape to the position above the SMT material tape to be attached to the SMT material tape. The drive device drives the pressure roller to roll the surfaces of the material-receiving tape and the SMT material tape which are attached to each other, so that the material-receiving tape and the SMT material tape completely adhere to each other and the success rate of covering the cover tape is improved. With such a device, two SMD tapes from two SMD component reels can be automatically connected.

### SUMMARY

The object of the invention is to provide a gripper for handling SMD component reel cassettes and an associated SMD component reel cassette, whereby the SMD tapes wound on the respective tape drum of the SMD component reel can be automatically unwound and/or automatically wound up.

The object is achieved by a gripper for handling SMD component reel cassettes by means of a robotic arm automatically controlled by a robot controller, when the robotic arm carries and manipulates the gripper on a tool flange of the robotic arm, comprising:
a gripper main body with a connecting flange for attaching the gripper to a tool flange of a robotic arm,
at least one coupling means for coupling an SMD component reel cassette to the gripper, on at least one end wall of the SMD component reel cassette, and
a drive pinion, which is rotatably mounted on the gripper main body and is designed to mesh with an output wheel of the SMD component reel cassette when the SMD component reel cassette is coupled to the gripper, and
a drive motor, which is disposed on the gripper main body and is designed to automatically drive the drive pinion.

An SMD component reel comprises a tape drum and an SMD tape wound on it. The SMD tape comprises a carrier tape, in particular with perforations on the edges at equal intervals for precise positioning of the carrier tape, and a plurality of SMD components which are applied to the carrier tape at equal intervals from one another in a serial chain. The SMD component reel can be housed in a cassette. The SMD component reels described below accordingly comprise a cassette in which the tape drum is stored together with the SMD tape wound on it.

The SMD component reel is rotatably mounted within the SMD component reel cassette. The SMD component reel cassette comprises an output wheel that can be driven by a drive pinion of the gripper guided by the robotic arm, wherein by driven rotation of the output wheel of the SMD component reel cassette, the SMD component reel can be automatically rotated for winding up or unwinding the SMD tape within the SMD component reel cassette in order to transport the SMD tape, in particular synchronously with an automatic movement of the SMD component reel cassette on its movement path between a change magazine of an SMD placement machine and a belt connector.

SMD placement machines are machines for automatically populating electronic circuit boards with electronic components. The components are generally automatically placed or glued onto the circuit board and then automatically connected to the circuit board's electrical conductor tracks, for example in a soldering bath, to create the electrical contacts. An SMD placement machine by way of example comprises a magazine station with unpopulated circuit boards, a conveyor system for feeding the circuit boards in a serial sequence, the actual placement machine, in which the required SMD components are picked up one after the other and placed on the respective circuit board at the designated locations, and an oven in which the SMD components placed on the circuit board are soldered. Lastly, the finished, i.e., populated, circuit boards can be stacked in a delivery magazine. This manufacturing process is largely automated. The large number of SMD components to be assembled are provided in a single type on an SMD component reel, each wound up as SMD tapes. Each individual SMD component requires its own SMD component reel. Each SMD component reel contains an SMD tape, which includes a carrier tape on which a plurality of SMD components of identical construction type are attached at regular intervals. Each SMD component type can be continuously fed to the SMD placement machine by means of the SMD component reel or by means of the SMD tape, so that the SMD placement machine can continuously and preferably without interruption populate the circuit boards with the required SMD components. However, if an SMD component reel is almost used up, i.e., almost all of the SMD components originally present on the SMD tape have been removed from the carrier tape and processed by the SMD placement machine, the used SMD component reel must be removed and replaced by a fully populated new SMD component reel. In order for the SMD placement machine to continue to manufacture uninterruptedly, the SMD tape of the new SMD component reel must be seamlessly attached to the end of the previous SMD tape of the idling SMD component reel. The joining should be carried out in such a way that on the joined carrier tape the distance of the first SMD component of the new SMD component reel from the last SMD component of the idling SMD component reel corresponds as closely as possible to the standardized distance of the plurality of SMD components from each other on an SMD component reel. Until now, this process of joining the beginning of the new SMD component reel to the idling SMD component reel is done manually and is generally not automated. This causes relatively high personnel costs and consistent quality is not guaranteed. Approaches already exist to automate the joining process for connecting the beginning of the new SMD component reel to the end of the idling SMD component reel, but the end of the idling SMD component reel and the beginning of the new SMD component reel still have to be introduced manually in these machines.

A gripper according to the disclosure and an SMD component reel cassette according to the disclosure are suitable aids for a fully automated reloading of new SMD component reels as successor rolls for idling SMD component reels, wherein an automatically operating belt connector can also be automatically loaded with the end of the idling SMD component reel and the beginning of the new SMD component reel by the robot-guided gripper proposed according to the invention, so that the end and the beginning can be automatically connected in the automatically operating belt connector.

First, there can be an automatic removal of a first SMD component reel cassette which carries a first SMD tape, which continues to run into the SMD placement machine during operation of the SMD placement machine. The first SMD component reel cassette is therefore firstly located in a change magazine of the SMD placement machine. The SMD placement machine works continuously automatically, in particular without interruption, so that during the automatic removal of the first SMD component reel cassette from the change magazine, the first SMD tape continues to be drawn into the SMD placement machine in order to remove the SMD components located on the first SMD tape one after the other within the SMD placement machine and to automatically populate circuit boards with them. When the first SMD component reel cassette is removed automatically, it must be ensured during the movements of the robotic arm, which automatically handles the first SMD component reel cassette by means of a gripper guided by the robotic arm, that no unacceptably high tensile forces are exerted on the first SMD tape running off the first SMD component reel. The SMD placement machine has a feeder that automatically feeds the first SMD tape into the SMD placement machine. This specifies a maximum tensile force that may act on the first SMD tape. On the other hand, a minimum tensile force should also be maintained to ensure that the first SMD tape is under a certain tensile stress, thus preventing the risk of loops forming or of the first SMD tape running off the first SMD component reel cassette in a bellying or jerky manner. The robot controller can therefore be designed and configured to move the robotic arm in such a way that during the automatic transport of the first SMD component reel cassette from the change magazine to the belt connector, the first SMD tape continuing to run out of the first SMD component reel is under the permissible, i.e., desired, tensile stress. This can be achieved in particular by the robot controller controlling the robotic arm in a force/torque-controlled mode of operation, so that the instantaneous tensile forces can be automatically recorded at any time during the automatic transport of the first SMD component reel cassette from the change magazine to the belt connector. The movement path that the robotic arm sets for the first SMD component reel cassette can therefore be adapted to this.

A second SMD component reel cassette, which carries a second SMD tape, can then be received from a receiving magazine by means of the robotic arm controlled by the robot controller. The second SMD component reel cassette will generally contain a new SMD component reel, i.e., a SMD component reel that is fully populated with SMD components. In so doing, the SMD component reel is in particular completely filled with the populated SMD tape. The receiving magazine can therefore form a storage location where completely filled SMD component reels or SMD component reel cassettes are kept in stock.

This allows a beginning portion of the second SMD tape to be automatically threaded into the automatic belt connector by means of the robotic arm controlled by the robot controller. For this purpose, the belt connector comprises a feed slot which is intended to temporarily receive the second SMD component reel cassette so that the respective beginning portion of the second SMD tape of the second SMD component reel cassette can be automatically grasped by the belt connector for the subsequent automatic connection of the end portion of the first SMD tape to the beginning portion of the second SMD tape.

Lastly, the second SMD component reel cassette can be automatically inserted into the change magazine of the SMD placement machine after the beginning portion of the second SMD tape of the second SMD component reel is automatically connected to the end portion of the first SMD tape in the tape connector.

Since the beginning portion of the second SMD tape of the second SMD component reel is already connected to the end portion of the first SMD tape at this point, a tensile force is already exerted on the second SMD tape during the automatic insertion of the second SMD component reel cassette into the change magazine of the SMD placement machine. As when removing the first SMD component reel cassette from the change magazine, the robotic arm controlled by the robot controller is also controlled in a force-/torque-controlled movement control manner when inserting the second SMD component reel cassette into the change magazine.

The tape drum of the respective (first or second) SMD component reel cassette can thus be rotatably mounted on at least one inner wall, in particular between two opposite inner walls of the housing of the cassette. The at least one inner wall can, for example, comprise an axle stub on which the SMD component reel can be rotatably attached. The SMD component reel can therefore be supported on one side on a single inner wall or on both sides on two opposite inner walls. The respective axle stub can comprise at least one latching projection on which the SMD component reel with its hub can be secured against axial loosening. One inner wall can be provided on a cover of the cassette. The cover can in particular be detachably attached to a main body of the cassette. The cover can be pivotably mounted on the main body of the cassette, for example by means of a hinge, for opening and closing. The output wheel can be firmly connected to the first SMD component reeler. The housing of the cassette can comprise at least one opening via which a gear ring of the output wheel is accessible from the outside. Via such an opening, a drive pinion can protrude into the housing of the cassette and mesh with the gear ring of the output wheel. If the drive pinion is driven, the output wheel can be rotated automatically, in particular selectively either clockwise or counterclockwise. The rotating output wheel moves the tape drum so that, depending on the direction of rotation, the SMD tape can either be actively unwound from the tape drum of the SMD component reel or actively wound up.

The drive pinion can be driven by a motor, in particular an electric motor. The drive pinion and in particular also the motor can be disposed on a gripper which is designed to automatically grip the SMD component reel cassette. The gripper can be attached to a tool flange of the robotic arm. Thus, the gripper can be moved by moving the robotic arm. Once the gripper has grasped the SMD component reel cassette, the robotic arm can move the SMD component reel cassette in space in the desired manner under the control of the robot controller. The gripper or the motor can be controlled by the robot controller, so that not only can the robot controller carry out the movement of the first SMD component reel cassette, but also the contained SMD tape can be automatically fed out of the cassette or drawn in as required and coordinated with the movements of the SMD component reel cassette in space.

Accordingly, a gripper according to the disclosure comprises a gripper main body which is provided with a connecting flange which serves to attach the gripper to a tool flange of a robotic arm.

The gripper comprises at least one coupling means for coupling an SMD component reel cassette to the gripper. The at least one coupling means is provided on at least one end wall of the SMD component reel cassette. By disposing the at least one coupling means on at least one end wall of the SMD component reel cassette, i.e., in particular on an end wall of the housing of the SMD component reel cassette, a plurality of SMD component reel cassettes can be stored directly next to one another, analogously to books lined up next to one another on a shelf, wherein the side surfaces of two adjacent SMD component reel cassettes facing one another can lie flush against one another, and yet can be automatically removed individually by the gripper without the gripper having to clamp an individual SMD component reel cassette on opposite side surfaces.

In a gripper according to the disclosure, a drive pinion is provided, which is rotatably mounted on the gripper main body and is designed to mesh with a output wheel of the SMD component reel cassette when the SMD component reel cassette is coupled to the gripper. The SMD component reel cassette and especially the output wheel disposed in this SMD component reel cassette are explained and disclosed in greater detail below.

The gripper also comprises a drive motor disposed on the gripper main body, which drive motor is designed to automatically drive the drive pinion.

When the gripper has gripped an SMD component reel cassette according to the invention, the drive pinion of the gripper is meshed with the output wheel of the SMD component reel cassette. This is ensured by the structural design of the gripper with a specific assignment of the position and location of the at least one coupling means of the gripper with respect to the position and location of the drive pinion of the gripper, and the structural design of the SMD component reel cassette with a specific assignment of the position and location of the at least one counter-coupling means of the SMD component reel cassette with respect to the position and location of the output wheel of the SMD component reel cassette.

The at least one coupling means can comprise at least one first latching means, which is designed for form-fitting engagement in a first counter-latching means on a first end wall of the SMD component reel cassette, and can comprise at least one second latching means, which is designed for form-fitting engagement in a second counter-latching means on a second end wall of the SMD component reel cassette, which is different from the first end wall of the SMD component reel cassette.

The at least one first latching means can be formed, for example, by a pin or a tenon. The pin or tenon may comprise a circular cross-section. The pin or tenon may extend transversely between two supporting walls of the gripper. The SMD component reel cassette can be inserted between the two opposite support walls of the gripper in a combined plugging and pivoting movement in order to couple the SMD component reel cassette to the gripper.

The gripper can comprise a locking means which is designed to lock itself in a form-fitting manner to a counter-locking means of the SMD component reel cassette when the SMD component reel cassette is coupled to the coupling means of the gripper, so that in a locking position of the locking means, an unintentional release of the SMD component reel cassette from the gripper is prevented and in an unlocking position of the locking means, the at least one coupling means can be moved out of the counter-locking means of the SMD component reel cassette by moving the gripper from the SMD component reel cassette in order to be able to release the gripper from the SMD component reel cassette.

The locking means can, for example, be a locking element which is mounted on the gripper in a linearly adjustable manner. The locking element can be connected to an actuator of a lifting magnet or a lifting cylinder in order to be able to automatically actuate, i.e., move, the locking element. The lifting magnet or the lifting cylinder can be electrically controlled for automatic adjustment of the locking element between its locking position and its unlocking position. The lifting magnet or the lifting cylinder can also be electrically driven.

The gripper may comprise a first support wall which is designed to lie flat against a first surface of the SMD component reel cassette when the SMD component reel cassette is coupled to the gripper.

Alternatively or in addition to a first support wall, the gripper can comprise a second support wall which is designed to lie flat against a second surface of the SMD component reel cassette when the SMD component reel cassette is coupled to the gripper.

Accordingly, an SMD component reel cassette coupled to the gripper can be guided through, or can be inserted between, two support walls of the gripper disposed opposite one another at a distance from one another.

The gripper can comprise a detection device which is designed and configured to automatically detect a marking on the SMD component reel cassette when the SMD component reel cassette is coupled to the gripper.

The object is also achieved by an SMD component reel cassette that matches the gripper, comprising a housing in which an SMD component reel is rotatably mounted, which contains an SMD tape wound on a tape drum of the SMD component reel, and comprising an output wheel coupled to the tape drum, which is designed to be driven by a drive pinion of a gripper guided by the robotic arm when the SMD component reel cassette is coupled to the gripper, wherein by driven rotation of the output wheel, the tape drum of the SMD component reel can be rotated selectively for winding or unwinding of the SMD tape within the SMD component reel cassette in order to transport the SMD tape out of or into the housing of the SMD component reel cassette.

The tape drum of the SMD component reel cassette can comprise an output hub to which a drive shaft connected to the output wheel is coupled, wherein the drive shaft is connected to the output wheel via a plurality of spokes, each of which comprises a curved course deviating from the radially straight direction towards the outside.

The SMD component reel cassette can comprise at least one counter-coupling means for coupling the SMD component reel cassette to a coupling means of a gripper on at least one end wall of its housing, in particular comprises a first counter-coupling means on a first end wall of the housing of the SMD component reel cassette and a second counter-coupling means on a second end wall of the housing of the SMD component reel cassette, which is different from the first end wall of the housing of the SMD component reel cassette, wherein the at least one counter-coupling means comprises at least one first counter-latching means that is designed for form-fitting engagement in a first latching means on the gripper and at least one second counter-latching means that is designed for form-fitting engagement in a second latching means on the gripper.

Alternatively or additionally, the SMD component reel cassette can comprise a counter-locking means which is designed to lock itself in a form-fitting manner to a locking means of the SMD component reel cassette when the SMD component reel cassette is coupled to a coupling means of the gripper, so that in a locking position of the locking means, an unintentional release of the SMD component reel cassette from the gripper is prevented and in an unlocking position of the locking means, the counter-locking means is released, so that the at least one coupling means of the gripper can be released from the at least one counter-coupling means by moving the gripper and the gripper can be removed from the SMD component reel cassette.

The locking means can, for example, be a locking element which is mounted on the gripper in a linearly adjustable manner. The locking element can be connected to an actuator of a lifting magnet or a lifting cylinder in order to be able to move the locking element automatically into the counter-locking means for locking or to be able to move it automatically out of the counter-locking means for unlocking. The counter-locking means can be a detent niche or a groove-like recess, for example in the first end wall of the housing of the SMD component reel cassette.

The housing of the SMD component reel cassette can comprise a grommet that extends outward tangentially from the tape drum of the SMD component reel and comprises a guide for an exiting or entering portion of the SMD tape wound on the tape drum, in particular the grommet is equipped with a braking device that is designed to clamp the portion of the SMD tape guided inside the grommet against the grommet in a blocking position in order to prevent unwanted movement of the SMD tape relative to the grommet, and to release the portion of the SMD tape guided inside the grommet in a release position so that the SMD tape can be transported through the grommet unhindered by the braking device.

The grommet can be formed by a type of spout, which includes a hollow channel with an outlet opening. The braking device can be pivotably mounted in the region of the outlet opening of the hollow channel. The braking device can be formed by a block which can be pivoted against the outlet opening of the hollow channel in order to clamp a portion of the SMD tape running through the hollow channel against the grommet. The clamping does not necessarily have to lead to the portion of SMD tape coming to a standstill and being clamped in place; rather, the clamping can also be so moderate that the friction is increased to a certain extent, so that the SMD tape can only be pulled out of the grommet with increased force, but can still be pulled out in principle. The pivotable braking device may comprise a tab which can form a lever. This allows the braking device to be opened or closed by the robotic arm, when it guides the SMD component reel cassette by means of its gripper, moving the tab in a suitable manner against an obstacle or a step, for example a step on the belt connector, whereby an external force can act on the lever-like tab in order to swing the braking device open or closed.

A data carrier can be attached to the housing of the SMD component reel cassette, and, in addition to its function as a data carrier, also forms a marking by means of which the robotic arm can automatically align itself with respect to the SMD component reel cassette to be gripped in order to be able to approach and grip the SMD component reel cassette detected via the marking in a precisely positioned manner by means of its gripper guided by the robotic arm.

The marking may, for example, be an optical marking and the detection device of the gripper can be a camera. The optical marking may comprise optical, particularly digital, marks, such as lines or dots. For example, the optical marking can be a barcode or a QR code. The marking can encode data, for example about the type and/or number of SMD components present on the SMD component reel stored in the SMD component reel cassette. The marking may also contain encoded data about the dimensions, i.e., the size and/or width of the cassette. The marking also includes markers that are disposed in a predefined position and location relative to a reference point of the housing of the SMD component reel cassette. The reference point on the SMD component reel cassette can, for example, be a point at the exit opening from which the SMD tape exits the cassette. Another reference point may be a location in the region of a gripping portion of the cassette for gripping by the gripper. The gripping portion can, for example, be a specific latching projection or a specific detent niche on the cassette.

By means of the gripper, the robotic arm, controlled by the robot controller, can handle a standardized cassette of identical design and size, wherein the standardized cassette is designed and configured to optionally store an SMD component reel of a specific size, a specific roll width, a specific roll diameter and/or a specific component type or to store an SMD component reel of a different size, a different roll width, a different roll diameter and/or a different component type.

By means of a gripper according to the disclosure and an SMD component reel cassette according to the disclosure, in particular a method for automatically reloading SMD component reels on SMD placement machines can be carried out, comprising the steps of:
automatically removing a first SMD component reel, which carries a first SMD tape, which continues to run into the SMD placement machine during operation of an SMD placement machine, while the first SMD component reel is removed from a change magazine of the SMD placement machine by means of a robotic arm controlled by a robot controller in a force-/torque-controlled movement control manner of the robotic arm,
automatically threading an end portion of the first SMD tape into an automatic belt connector by means of the robotic arm controlled by the robot controller and automatically separating the first SMD component reel from the first SMD tape,
placing the first SMD component reel in an intermediate storage magazine,
receiving a second SMD component reel carrying a second SMD tape from a receiving magazine by means of the robotic arm controlled by the robot controller,
automatically threading a starting portion of the second SMD tape into the automatic tape connector by means of the robotic arm controlled by the robot controller, and
automatically inserting the second SMD component reel into the change magazine of the SMD placement machine after a beginning portion of the second SMD tape of the second SMD component reel is automatically connected to the end portion of the first SMD tape in the belt connector, while the second SMD tape runs off the second SMD component reel during operation of the SMD placement machine, wherein the insertion of the second SMD component reel into the change magazine of the SMD placement machine takes place by means of the robotic arm controlled by the robot controller in a force/torque-controlled movement control manner of the robotic arm.

Specific embodiments of the invention are explained in more detail in the following description with reference to the accompanying drawings. Specific features of these embodiments, possibly considered individually or in further combinations, can represent general features of the invention, regardless of the specific context in which they are mentioned.

### BRIEF DESCRIPTION OF THE DRAWINGS

The accompanying drawings, which are incorporated in and constitute a part of this specification, illustrate exemplary embodiments of the invention and, together with a general description of the invention given above, and the detailed description given below, serve to explain the principles of the invention.

FIG. 1 shows a schematic representation of three SMD placement machines by way of example, each with a change magazine in which a plurality of SMD component reels are inserted,

FIG. 2 shows a flow chart of the steps in a basic method, in accordance with which a gripper and an SMD component reel cassette according to the disclosure can be used,

FIG. 3 shows a perspective representation of an autonomous vehicle by way of example with a robotic arm, a belt connector and an intermediate storage magazine in a view from the left side of the vehicle,

FIG. 4 shows a perspective representation of the autonomous vehicle by way of example with the robotic arm, the belt connector and the intermediate storage magazine in a view from the right side of the vehicle,

FIG. 5 shows a perspective representation of the autonomous vehicle by way of example with the robotic arm, the belt connector and the intermediate storage magazine in a view from behind,

FIG. 6 shows a perspective representation of the autonomous vehicle by way of example with the robotic arm, the belt connector and the intermediate storage magazine in a view from the front,

FIG. 7 shows a perspective representation of the gripper by way of example to which an SMD component reel cassette by way of example is coupled, in which an SMD component reel by way of example is stored,

FIG. 8 shows a schematic representation of the SMD component reel cassette in which an SMD component reel by way of example is stored, in isolation,

FIG. 9 shows a schematic representation of the SMD component reel cassette in which the SMD component reel by way of example is stored with a coupled gripper according to the disclosure, which is attached to the flange of the robotic arm,

FIG. 10 shows a perspective partial view of the SMD component reel cassette in the region of the exit spout of the SMD tape, in a closed position of a locking means,

FIG. 11 shows a perspective partial representation of the SMD component reel cassette in the region of the exit spout of the SMD tape, in an open position of the locking means,

FIG. 12 shows a schematic representation in a side view of a gripper by way of example according to the disclosure in isolation, and

FIG. 13 shows a perspective representation of the gripper by way of example in accordance with FIG. 12 in isolation.

### DETAILED DESCRIPTION

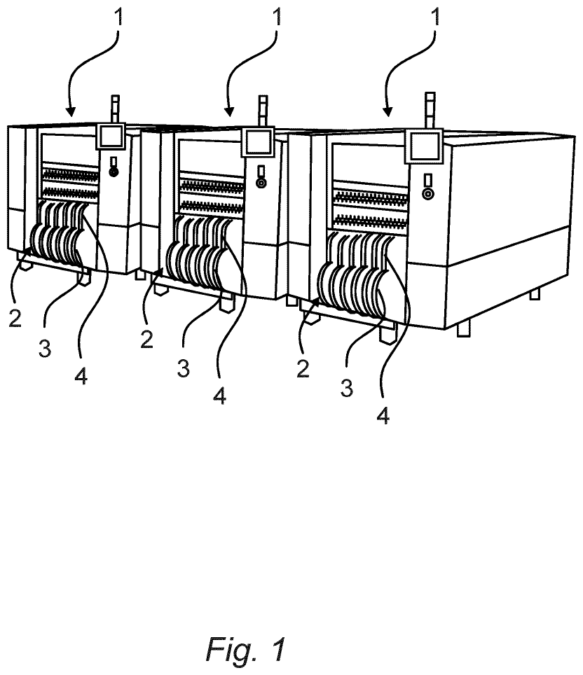

In FIG. 1, three representative SMD placement machines 1 are shown. Each SMD placement machine 1 has a change magazine 2 in which a plurality of different SMD component reels 3 are inserted. From each SMD component reel 3, an SMD tape 4 runs into the associated SMD placement machine 1. Each SMD component reel 3 can be stored in its own SMD component reel cassette 10.1, 10.2.

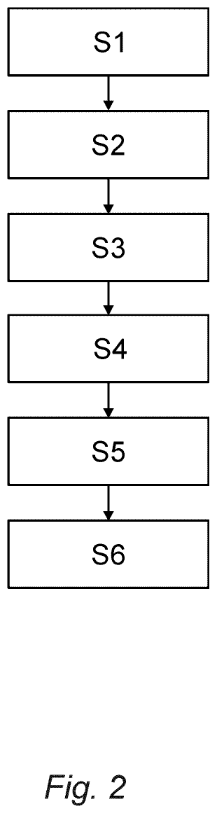

FIG. 2 shows a method by way of example for automatically reloading SMD component reels 3 or SMD component reel cassettes 10.1, 10.2 on SMD placement machines 1, schematically as a flow chart.

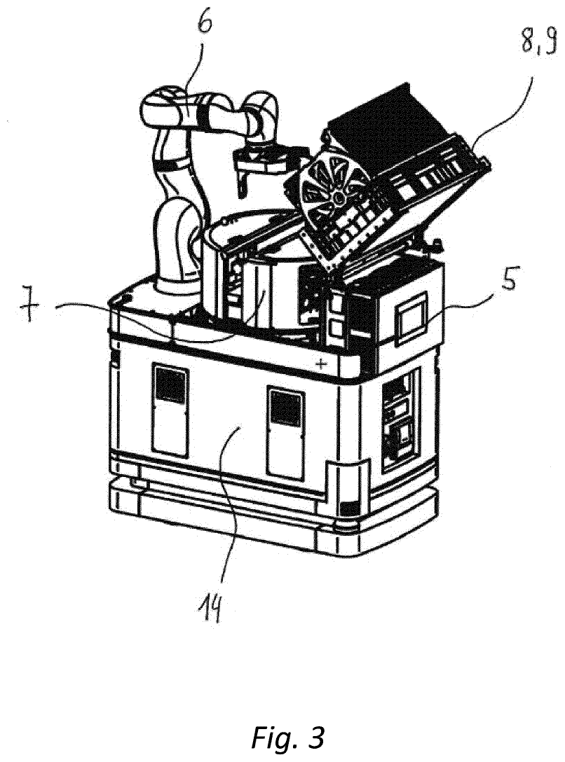

In a first method step S1, a first SMD component reel cassette 10.1 is automatically removed and carries a first SMD tape 4.1, which continues to run into the SMD placement machine 1 during operation of an SMD placement machine 1, while the first SMD component reel cassette 10.1 is removed from a change magazine 2 of the SMD placement machine 1 by means of a robotic arm 6 (FIG. 3) controlled by a robot controller 5 in a force-/torque-controlled movement control manner of the robotic arm 6.

In a second method step S2, an end portion of the first SMD tape 4.1 is automatically threaded into an automatic belt connector 7 by means of the robotic arm 6 controlled by the robot controller 5 and the first SMD component reel cassette 10.1 is automatically separated from the first SMD tape 4.1.

In a third method step S3, the first SMD component reel cassette 10.1 is deposited in an intermediate storage magazine 8.

In a fourth method step S4, a second SMD component reel cassette 10.2, which carries a second SMD tape 4.2, is received from a receiving magazine 9 by means of the robotic arm 6 controlled by the robot controller 5.

In a fifth method step S5, a beginning portion of the second SMD tape 4.2 is automatically threaded into the automatic belt connector 7 by means of the robotic arm 6 controlled by the robot controller 5.

In a sixth method step S6, the second SMD component reel cassette 10.2 is automatically inserted into the change magazine 2 of the SMD placement machine 1 after a beginning portion of the second SMD tape 4.2 of the second SMD component reel 3.2 is automatically connected to the end portion of the first SMD tape 4.1 in the belt connector 7, while the second SMD tape 4.2 runs from the second SMD component reel 3.2 out of the second SMD component reel cassette 10.2 during operation of the SMD placement machine 1, wherein the second SMD component reel cassette 10.2 is inserted into the change magazine 2 of the SMD placement machine 1 by means of the robotic arm 6 controlled by the robot controller 5 in a force-/torque-controlled movement control manner of the robotic arm 6.

The robotic arm 6 is controlled by the robot controller 5 such that the first SMD component reel cassette 10.1 is guided on its way between the change magazine 2 of the SMD placement machine 1 and the belt connector 7 by the robotic arm 6 on a movement path which lies at least substantially in a plane which runs parallel to the feed direction of the first SMD tape 4.1 of the first SMD component reel cassette 10.1 into the SMD placement machine 1.

The robotic arm 6 is also controlled by the robot controller 5 in such a way that the second SMD component reel cassette 10.2 is guided on its way between the belt connector 7 and the change magazine 2 of the SMD placement machine 1 by the robotic arm 6 on a movement path which lies at least substantially in a plane which runs parallel to the feed direction of the second SMD tape 4.2 of the second SMD component reel 3.2 into the SMD placement machine 1.

The robotic arm 6 can be controlled by the robot controller 5 in such a way that the first SMD component reel cassette 10.1 is guided on its way between the change magazine 2 of the SMD placement machine 1 and the belt connector 7 by the robotic arm 6 on a movement path on which the first SMD component reel cassette 10.1 does not rotate or only rotates exclusively about its roll rotation axis. The robotic arm 6 can also be controlled by the robot controller 5 in such a way that the second SMD component reel cassette 10.2 can be guided on its way between the belt connector 7 and the change magazine 2 of the SMD placement machine 1 by the robotic arm 6 on a movement path on which the second SMD component reel cassette 10.2 does not rotate or only rotates exclusively about its roll rotation axis.

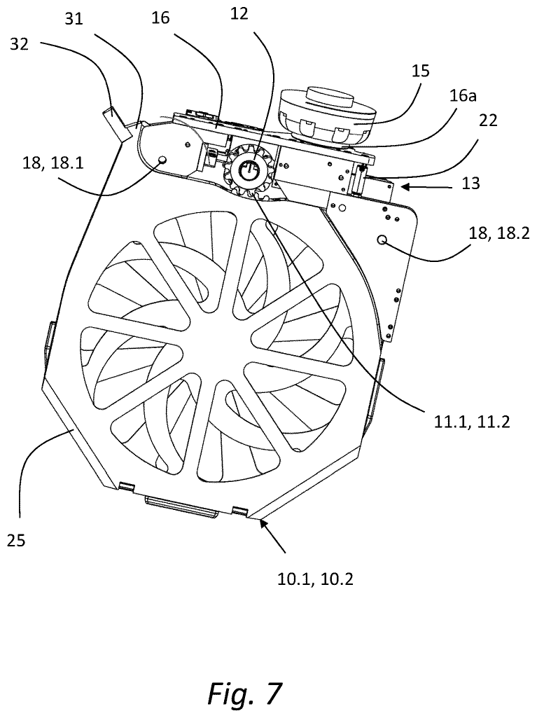

In FIG. 7 to FIG. 13, the gripper 13 for handling SMD component reel cassettes 10.1, 10.2 is shown. The handling is carried out by means of a robotic arm 6 which is automatically controlled by a robot controller 5 when the robotic arm carries and manipulates the gripper 13 on the tool flange 15 of the robotic arm.

The gripper 13 comprises a gripper main body 16 with a connecting flange 16a for attaching the gripper 13 to a tool flange 15 of a robotic arm 6, as shown in particular in FIG. 7.

At least one coupling means 18 serves to couple an SMD component reel cassette 10.1, 10.2 to the gripper 13, to at least one end wall 19.1, 19.2 of the SMD component reel cassette 10.1, 10.2. The coupling means 18 latch with counter-coupling means 20 of the SMD component reel cassette 10.1, 10.2.

A drive pinion 12 which is rotatably mounted on the gripper main body 16 of the gripper 13 and which is designed to mesh with a output wheel 11, 11.2 of the SMD component reel cassette 10.1, 10.2 in a state of the SMD component reel cassette 10.1, 10.2 coupled to the gripper 13 (FIG. 7).

The gripper 13 also comprises a drive motor 17 disposed on the gripper main body 16, which drive motor is designed to automatically drive the drive pinion 12.

The at least one coupling means 18 comprises at least one first latching means 18.1, which is designed for form-fitting engagement in a first counter-latching means 20.1 on a first end wall 19.1 of the SMD component reel cassette 10.1, 10.2, and at least one second latching means 18.2, which is designed for form-fitting engagement in a second counter-latching means 20.2 on a second end wall 19.2 of the SMD component reel cassette 10.2, 10.2, which is different from the first end wall 19.1 of the SMD component reel cassette 10.1, 10.2.

The at least one first latching means 18.1 can be formed, for example, by a pin or a tenon. The pin or tenon may comprise a circular cross-section. The pin or tenon can extend transversely between two supporting walls 21.1, 2.12 of the gripper 13. The SMD component reel cassette 10.1, 10.2 can be inserted between the two opposite support walls 21.1, 2.12 of the gripper 13 in a combined plugging and pivoting movement in order to couple the SMD component reel cassette 10.1, 10.2 to the gripper.

In the case of the present exemplary embodiment, the gripper 13 also comprises an adjustable locking means 22 which is designed to lock itself in a form-fitting manner to a counter-locking means of the SMD component reel cassette 10.1, 10.2 when the SMD component reel cassette 10.1, 10.2 is coupled to the coupling means 18 of the gripper 13, so that in a locking position of the locking means 22, an unintentional release of the SMD component reel cassette 10.1, 10.2 from the gripper 13 is prevented and in an unlocking position of the locking means 22, the at least one coupling means 18 can be moved out of the counter-locking means of the SMD component reel cassette 10.1, 10.2 by moving the gripper 13 from the SMD component reel cassette 10.1, 10.2 in order to be able to release the gripper 13 from the SMD component reel cassette 10.1, 10.2.

The locking means 22 can, for example, be a locking element which is mounted on the gripper 13 in a linearly adjustable manner. The locking element can be connected to an actuator of a lifting magnet or a lifting cylinder in order to be able to automatically actuate, i.e., move, the locking element. The lifting magnet or the lifting cylinder can be electrically controlled for automatic adjustment of the locking element between its locking position and its unlocking position. The lifting magnet or the lifting cylinder can also be electrically driven.

The gripper 13 comprises a first support wall 21.1, which is designed to lie flat against a first surface of the SMD component reel cassette 10.1, 10.2 when the SMD component reel cassette 10.1, 10.2 is coupled to the gripper 13, and the gripper 13, in the case of the present exemplary embodiment, also comprises a second support wall 21.2, which is designed to lie flat against a second surface of the SMD component reel cassette 10.1, 10.2 when the SMD component reel cassette 10.1, 10.2 is coupled to the gripper 13.

Accordingly, an SMD component reel cassette 10.1, 10.2 coupled to the gripper 13 can be guided in particular by two support walls 21.1, 21.2 of the gripper 13 disposed opposite one another at a distance from one another, or can be inserted between them.

The gripper 13 can comprise a detection device 23 which is designed and configured to automatically detect a marking 24 on the SMD component reel cassette 10.1, 10.2 when the SMD component reel cassette 10.1, 10.2 is coupled to the gripper 13.

In particular, FIG. 7 to FIG. 11 show an SMD component reel cassette 10.1, 10.2, comprising a housing 25 in which an SMD component reel 3.1, 3.2 is rotatably mounted, which contains an SMD tape 4.1, 4.2 wound on a tape drum 26 of the SMD component reel 3.1, 3.2, and comprising an output wheel 11.1, 11.2 coupled to the tape drum 26, which is designed to be driven by a drive pinion 12 of a gripper 13 guided by the robotic arm 6 when the SMD component reel cassette 10.1, 10.2 is coupled to the gripper 13, wherein by driven rotation of the output wheel 11.1, 11.2, the tape drum 26 of the SMD component reel 3.1, 3.2 can be rotated selectively for winding or unwinding of the SMD tape 4.1, 4.2 within the SMD component reel cassette 10.1, 10.2 in order to transport the SMD tape 4.1, 4.2 out of or into the housing 25 of the SMD component reel cassette 10.1, 10.2.

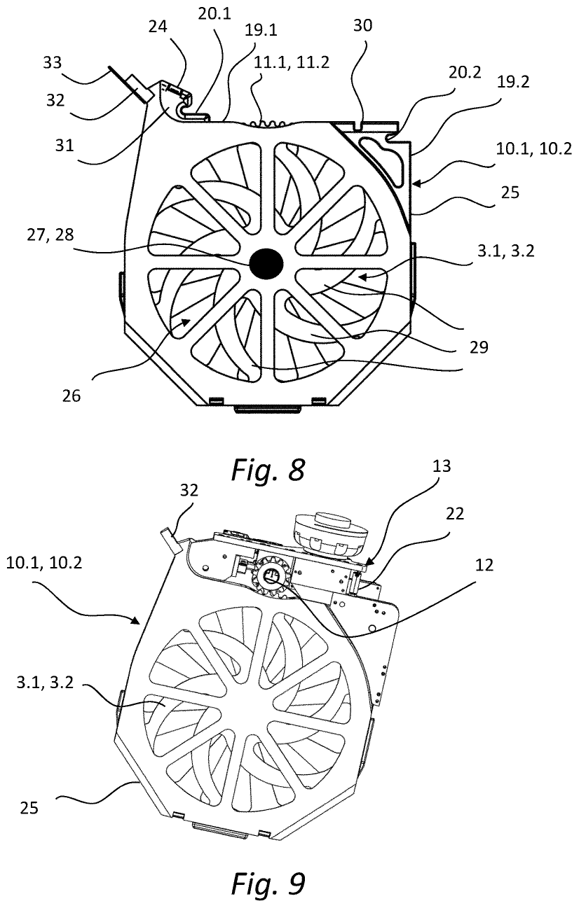

The tape drum 26 comprises an output hub 27 to which a drive shaft 28 connected to the output wheel 11.1, 11.2 is coupled, wherein the drive shaft 28 is connected to the output wheel 11.1, 11.2 via a plurality of spokes 29, each of which comprises a curved course deviating from the radially straight direction towards the outside, as is shown in particular in FIG. 8 and FIG. 9.

The SMD component reel cassette 10.1, 10.2 comprises at least one counter-coupling means 20 for coupling the SMD component reel cassette 10.1, 10.2 to the coupling means 18 of the gripper 13 on at least one end wall 19.1, 19.2 of the housing 25 of the SMD component reel cassette, in particular a first counter-coupling means 20 on a first end wall 19.1 of the housing 25 of the SMD component reel cassette 10.1, 10.2 and a second counter-coupling means 20 on a second end wall 19.2 of the housing 25 of the SMD component reel cassette 10.1, 10.2, which is different from the first end wall 19.1 of the housing 25 of the SMD component reel cassette 10.1, 10.2, wherein the at least one counter-coupling means 20 comprises at least one first counter-latching means (first groove) that is designed for form-fitting engagement in a first latching means (first pin or first tenon) on the gripper 13 and at least one second counter-latching means (second groove) that is designed for form-fitting engagement in a second latching means (second pin or second pin) on the gripper 13.

As can be seen in particular in FIG. 8 and FIG. 9, in the case of the present embodiment, the SMD component reel cassette 10.1, 10.2 comprises a counter-locking means 30 which is designed to lock itself in a form-fitting manner to the locking means 22 of the SMD component reel cassette 10.1, 10.2 when the SMD component reel cassette 10.1, 10.2 is coupled to a coupling means 18 of the gripper 13, so that in a locking position of the locking means 22, an unintentional release of the SMD component reel cassette 10.1, 10.2 from the gripper 13 is prevented and in an unlocking position of the locking means 22, the counter-locking means 30 is released, so that the at least one coupling means 18 of the gripper 13 can be released from the at least one counter-coupling means 20 by moving the gripper 13 and the gripper 13 can be removed from the SMD component reel cassette 10.1, 10.2.

The locking means 22 can, for example, be a locking element which is mounted on the gripper 13 in a linearly adjustable manner. The locking element can be connected to an actuator of a lifting magnet or a lifting cylinder in order to be able to move the locking element automatically into the counter-locking means 30 for locking or to be able to move it automatically out of the counter-locking means 30 for unlocking. The counter-locking means 30 can accordingly, as shown in particular in FIG. 8, be a detent niche or a groove-like recess, for example in the first end wall 19.1 of the housing 25 of the SMD component reel cassette 10.1, 10.2.

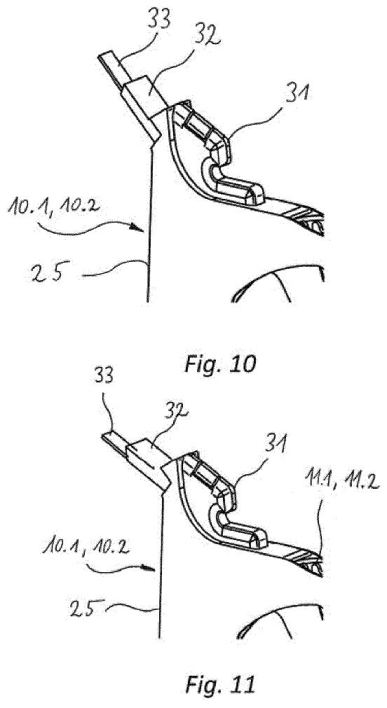

The housing 25 of the SMD component reel cassette 10.1, 10.2 can, as shown in particular in FIG. 10 and FIG. 11, comprise a grommet 31 extending outwards tangentially from the tape drum 26 of the SMD component reel 3.1, 3.2, which grommet comprises a guide for an exiting or entering portion of the SMD tape 4.1, 4.2 wound on the tape drum 26. The grommet 31 can be equipped with a braking device 32 which is designed to clamp the portion of the SMD tape 4.1, 4.2 guided inside the grommet 31 against the grommet 31 in a blocking position in accordance with FIG. 10 in order to prevent an undesired movement of the SMD tape 4.1, 4.2 relative to the grommet 31, and to release the portion of the SMD tape 4.1, 4.2 guided inside the grommet 31 in a release position in accordance with FIG. 11 so that the SMD tape 4.1, 4.2 can be transported through the grommet 31 unhindered by the braking device 32. In FIG. 10, the braking device 32 is therefore pivoted upwards and in FIG. 11, pivoted downwards.

The grommet 31 can be formed by a type of spout, which includes a hollow channel with an outlet opening. The braking device 32 can be pivotably mounted in the region of the outlet opening of the hollow channel. The braking device 32 can be formed by a block which can be pivoted against the outlet opening of the hollow channel in order to clamp a portion of the SMD tape 4.1, 4.2 running through the hollow channel against the grommet. The clamping does not necessarily have to lead to the portion of the SMD tape 4.1, 4.2 coming to a standstill and being clamped in place; rather, the clamping can also be so moderate that the friction is increased to a certain extent, so that the SMD tape 4.1, 4.2 can only be pulled out of the grommet 31 with increased force, but can still be pulled out in principle. The pivotable braking device 32 may comprise a tab 33 which can form a lever. This allows the braking device 32 to be opened or closed by the robotic arm 6, when it guides the SMD component reel cassette 10.1, 10.2 by means of its gripper 13, moving the tab 33 in a suitable manner against an obstacle or a step, for example a step on the belt connector 7, whereby an external force can act on the lever-like tab 33 in order to swing the braking device 32 open or closed.

A data carrier can be attached to the housing 25 of the SMD component reel cassette 10.1, 10.2, and, in addition to its function as a data carrier, also forms a marking 24 by means of which the robotic arm 6 can automatically align itself with respect to the SMD component reel cassette 10.1, 10.2 to be gripped in order to be able to approach and grip the SMD component reel cassette 10.1, 10.2 detected via the marking in a precisely positioned manner by means of its gripper 13 guided by the robotic arm 6.

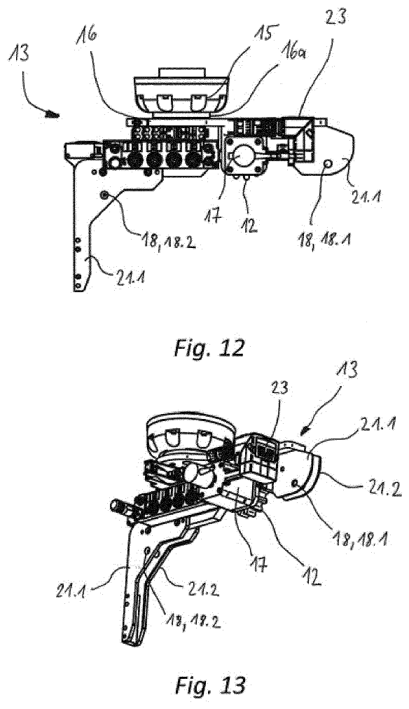

The first SMD component reel 3.1 can be rotatably mounted in a first SMD component reel cassette 10.1, as shown in FIG. 7 to FIG. 11, which comprises at least one first output wheel 11.1 that can be driven by a drive pinion 12 (FIG. 9) of a gripper 13 (FIG. 12 and FIG. 13) guided by the robotic arm 6, wherein by driven rotation of the first output wheel 11.1 of the first SMD component reel cassette 10.1, the first SMD component reel 3.1 is rotated within the first SMD component reel cassette 10.1 for winding up or unwinding the first SMD tape 4.1 in order to move the first SMD tape 4.1 synchronously with the automatic movement of the first SMD component reel cassette 10.1 on its movement path between the change magazine 2 of the SMD placement machine 1 and the belt connector 7.

In the same way, the second SMD component reel 3.2 can be rotatably mounted in a second SMD component reel cassette 110.2, which comprises at least one second output wheel 11.2 that can be driven by the drive pinion 12 of the gripper 13 guided by the robotic arm 6 (FIG. 12 and FIG. 13), wherein by driven rotation of the second output wheel 11.2 of the second SMD component reel cassette 10.2, the second SMD component reel 3.2 is rotated within the second SMD component reel cassette 10.2 for winding up or unwinding the second SMD tape 4.2 in order to transport the second SMD tape 4.2 synchronously with the automatic movement of the second SMD component reel cassette 10.2 on its movement path between the belt connector 7 and the change magazine 2 of the SMD placement machine 1.

The automatic threading of the end portion of the first SMD tape 4.1 into the automatic belt connector 7 is carried out by means of the robotic arm 6 controlled by the robot controller 5 in a force-/torque-controlled movement control manner of the robotic arm 6. The automatic insertion of the beginning portion of the second SMD tape 4.2 into the automatic belt connector 7 by means of the robotic arm 6 controlled by the robot controller 5 is also carried out in a force/torque-controlled movement control manner of the robotic arm 6.

The robotic arm 6, controlled by the robot controller 5, handles a standardized SMD component reel cassette 10.1, 10.2 of identical design and size, wherein the standardized SMD component reel cassette 10.1, 10.2 is designed and configured to optionally store an SMD component reel 3.1, 3.2 of a specific size, a specific roll width, a specific roll diameter and/or a specific component type or to store an SMD component reel 3.1, 3.2 of a different size, a different roll width, a different roll diameter and/or a different component type.

The standardized SMD component reel cassette 10.1, 10.2 can comprise a data carrier which, in addition to its function as a data carrier, also forms a marking by means of which the robotic arm 6 can automatically align itself with respect to the SMD component reel cassette 10.1, 10.2 to be gripped in order to be able to approach and grip the SMD component reel cassette 10.1, 10.2 detected via the marking in a precisely positioned manner by means of its gripper 13 guided by the robotic arm 6.

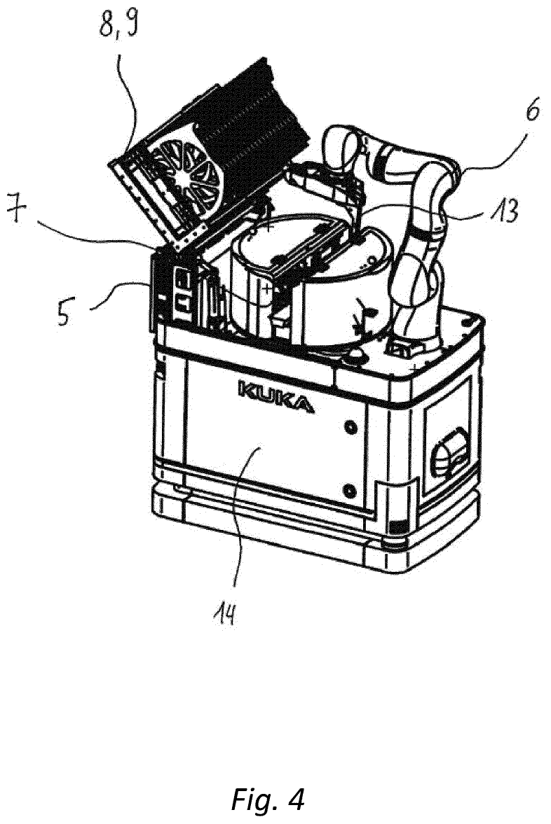

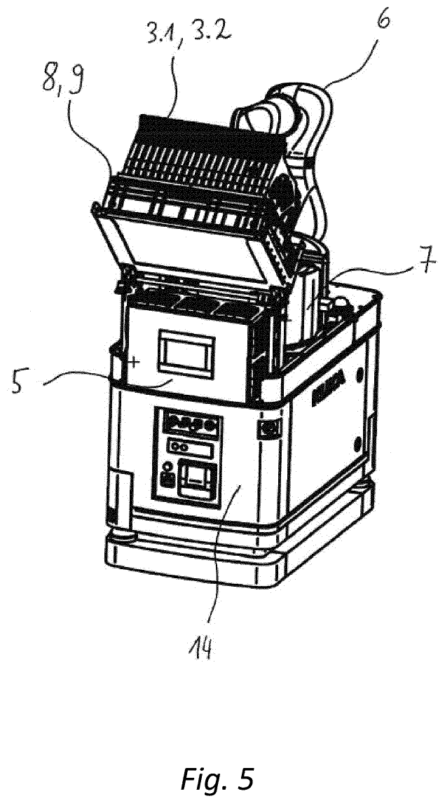

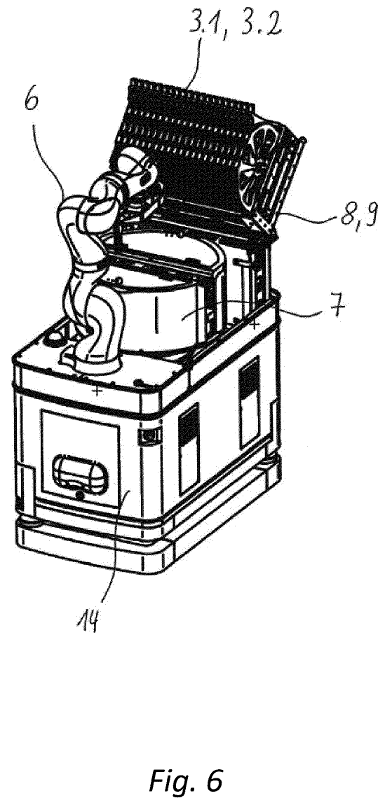

As shown in FIG. 3 to FIG. 6, in the case of the present exemplary embodiment, the robotic arm 6 is disposed on an autonomous vehicle 14 and the autonomous vehicle 14 is designed to automatically move the robotic arm 6 between a supply location, at which SMD component reels 10.1, 10.2 populated with SMD components are provided for transport to an SMD placement machine 1 in SMD component reel cassettes 10.1, 10.2, and the change magazine 2 of the SMD placement machine 1, into which at least one provided SMD component reel cassette 10.1, 10.2 is to be loaded.

While the present invention has been illustrated by a description of various embodiments, and while these embodiments have been described in considerable detail, it is not intended to restrict or in any way limit the scope of the appended claims to such de-tail. The various features shown and described herein may be used alone or in any combination. Additional advantages and modifications will readily appear to those skilled in the art. The invention in its broader aspects is therefore not limited to the specific details, representative apparatus and method, and illustrative example shown and described. Accordingly, departures may be made from such details without departing from the spirit and scope of the general inventive concept.

What is claimed is:

1. A gripper for handling SMD component reel cassettes (10.1, 10.2) by means of a robotic arm (6) automatically controlled by a robot controller (5), when the robotic arm carries and manipulates the gripper (13) on a tool flange (15) of the robotic arm, comprising:
a gripper main body (16) with a connecting flange (16a) for attaching the gripper (13) to a tool flange (15) of a robotic arm (6),
at least one coupling means (18) to couple an SMD component reel cassette (10.1, 10.2) to the gripper (13), to at least one end wall (19.1, 19.2) of the SMD component reel cassette (10.1, 10.2), and
a drive pinion (12) which is rotatably mounted on the gripper main body (16) and which is designed to mesh with an output wheel (11.1, 11.2) of the SMD component reel cassette (10.1, 10.2) in a state of the SMD component reel cassette (10.1, 10.2) coupled to the gripper (13), and
a drive motor (17), which is disposed on the gripper main body (16) and is designed to automatically drive the drive pinion (12).

2-10. (canceled)

11. The gripper according to claim 1, characterized in that the at least one coupling means (18) comprises at least one first latching means (18.1) which is de-signed for form-fitting engagement in a first counter-latching means (20.1) on a first end wall (19.1) of the SMD component reel cassette (10.1, 10.2) and comprises at least one second latching means (18.2) which is designed for form-fitting engagement in a second counter-latching means (20.2) on a second end wall (19.2) of the SMD component reel cassette (10.1, 10.2), which is different from the first end wall (19.1) of the SMD component reel cassette (10.1, 10.2).

12. The gripper according to claim 1, characterized in that the gripper (13) comprises a locking means (22) which is designed to lock itself in a form-fitting manner to a counter-locking means (30) of the SMD component reel cassette (10.1, 10.2) when the SMD component reel cassette (10.1, 10.2) is coupled to the coupling means (18) of the gripper (13), so that in a locking position of the locking means (22), an unintentional release of the SMD component reel cassette (10.1, 10.2) from the gripper (13) is prevented and in an unlocking position of the locking means (22), the at least one coupling means (18) can be moved out of the counter-locking means (30) of the SMD component reel cassette (10.1, 10.2) by moving the gripper (13) from the SMD component reel cassette (10.1, 10.2) in order to be able to release the gripper (13) from the SMD component reel cassette (10.1, 10.2).

13. The gripper according to claim 1, characterized in that the gripper (13) comprises a first support wall (21.1), which is designed to lie flat against a first surface of the SMD component reel cassette (10.1, 10.2) when the SMD component reel cassette (10.1, 10.2) is coupled to the gripper (13) and/or the gripper (13) comprises a second support wall (21.2), which is designed to lie flat against a second surface of the SMD component reel cassette (10.1, 10.2) when the SMD component reel cassette (10.1, 10.2) is coupled to the gripper (13).

14. The gripper according to claim 1, characterized in that the gripper (13) comprises a detection device (23) which is designed and configured to automatically detect a marking (24) on the SMD component reel cassette (10.1, 10.2) when the SMD component reel cassette (10.1, 10.2) is coupled to the gripper (13).

15. An SMD component reel cassette, comprising a housing (25) in which an SMD component reel (3.1, 3.2) is rotatably mounted, which contains an SMD tape (4.1, 4.2) wound on a tape drum (26) of the SMD component reel (3.1, 3.2), and comprising an output wheel (11.1, 11.2) coupled to the tape drum, which is de-signed to be driven by a drive pinion (12) of a gripper (13) guided by the robotic arm (6) when the SMD component reel cassette (10.1, 10.2) is coupled to the gripper (13), wherein by driven rotation of the output wheel (11.1, 11.2), the tape drum (26) of the SMD component reel (10.1, 10.2) can be rotated selectively for winding or unwinding of the SMD tape (4.1, 4.2) within the SMD component reel cassette (10.1, 10.2) in order to transport the SMD tape (4.1, 4.2) out of or into the housing (25) of the SMD component reel cassette (10.1, 10.2).

16. The SMD component reel cassette according to claim 15, characterized in that the tape drum (26) comprises an output hub (27) to which a drive shaft (28) connected to the output wheel (11.1, 11.2) is coupled, wherein the drive shaft (28) is connected to the output wheel (11.1, 11.2) via a plurality of spokes (29), each of which comprises a curved course, deviating from the radially straight direction towards the outside.

17. The SMD component reel cassette according to claim 15, characterized in that the SMD component reel cassette (10.1, 10.2) comprises at least one counter-coupling means (20.1, 20.2) on at least one end wall (19.1, 19.2) of its housing (25) for coupling the SMD component reel cassette (10.1, 10.2) to a coupling means (18) of a gripper (13), in particular a first counter-coupling means (20) on a first end wall (19.1) of the housing (25) of the SMD component reel cassette (10.1, 10.2) and a second counter-coupling means (20) on a second end wall (19.2) of the housing (25) of the SMD component reel cassette (10.1, 10.2), which is different from the first end wall (19.1) of the housing (25) of the SMD component reel cassette (10.1, 10.2), wherein the at least one counter-coupling means (20) comprises at least one first counter-latching means (20.1) which is designed for form-fitting engagement in a first latching means (18.1) on the gripper (13) and at least one second counter-latching means (20.2) which is designed for form-fitting engagement in a second latching means (18.2) on the gripper (13), and/or the SMD component reel cassette (10.1, 10.2) comprises a counter-locking means (30) which is designed to lock itself in a form-fitting manner to a locking means (22) of the SMD component reel cassette (10.1, 10.2) in a state in which the SMD component reel cassette (10.1, 10.2) is coupled to a coupling means (18) of the gripper (13), so that in a locking position of the locking means (22) an unintentional release of the SMD component reel cassette (10.1, 10.2) from the gripper (13) is prevented and in an unlocking position of the locking means (22) the counter-locking means (30) is released, so that the at least one coupling means (18) of the gripper (13) can be released from the at least one counter-coupling means (20) by moving the gripper (13) and the gripper (13) can be removed from the SMD component reel cassette (10.1, 10.2).

18. The SMD component reel cassette according to claim 15, characterized in that the housing (25) comprises a grommet (31) that extends outward tangentially from the tape drum (26) of the SMD component reel (3.1, 3.2) and comprises a guide for an exiting or entering portion of the SMD tape (4.1, 4.2) wound on the tape drum (26), in particular the grommet (31) is equipped with a braking device (32) that is designed to clamp the portion of the SMD tape (4.1, 4.2) guided inside the grommet (31) against the grommet (31) in a blocking position in order to prevent unwanted movement of the SMD tape (4.1, 4.2) relative to the grommet (31), and to release the portion of the SMD tape (4.1, 4.2) guided inside the grommet (31) in a release position so that the SMD tape (4.1, 4.2) can be transported through the grommet (31) unhindered by the braking device (32).

19. The SMD component reel cassette according to claim 15, characterized in that a data carrier is attached to the housing (25) of the SMD component reel cassette (10.1, 10.2), and, in addition to its function as a data carrier, also forms a marking (24) by means of which the robotic arm (6) can automatically align itself with respect to the SMD component reel cassette (10.1, 10.2) to be gripped in order to be able to approach and grip the SMD component reel cassette (10.1, 10.2) detected via the marking in a precisely positioned manner by means of its gripper (13) guided by the robotic arm (6).
